(19) United States
(12) Patent Application Publication
(10) Pub. No.: US 2013/0334431 A1
(43) Pub. Date: Dec. 19, 2013

(54) DETECTING APPARATUS AND RADIATION DETECTING SYSTEM

(71) Applicant: CANON KABUSHIKI KAISHA, TOKYO (JP)

(72) Inventors: Tomoaki Ichimura, Kitamoto-shi (JP); Shoshiro Saruta, Kodama-gun (JP)

(21) Appl. No.: 13/920,186

(22) Filed: Jun. 18, 2013

(30) Foreign Application Priority Data
Jun. 19, 2012 (JP) 2012-138074

(51) Int. Cl. H01L 27/146

(52) U.S. Cl. CPC H01L 27/1462
USPC 250/370.01; 257/59; 257/72

(57) ABSTRACT

In order to provide a detecting apparatus which is able to reduce unevenness in image even if an organic material is used for a protective layer covering a plurality of photoeectric conversion elements, the detecting apparatus includes a plurality of photoelectric conversion elements, a protective layer made from an organic material, provided so as to cover the plurality of photoelectric conversion elements, and a conductive member provided between the plurality of photoelectric conversion elements and the protective layer so as to cover the plurality of photoelectric conversion elements and receiving a predetermined potential.

### BACKGROUND OF THE INVENTION

1. Field of the Invention

The present invention relates to a detecting apparatus and a radiation detecting system.

2. Description of the Related Art

A technique of manufacturing a panel for a liquid crystal display using a thin film transistor (TFT) is being developed these days, thereby developing a large-sized panel and a large-sized screen of a display unit. This manufacturing technique is applied to a large-sized area sensor including photoelectric conversion elements constituted by a semiconductor and switching elements such as TFTs. Such an area sensor is used in a field of a radiation detecting apparatus such as a medical X-ray detecting apparatus in combination with a scintillator which converts radiation such as an X-ray into light such as visible light.

An example of the scintillator which converts radiation into visible light is a scintillator made from an alkali halide system material represented by a material in which Tl is doped on cesium iodide (hereinafter referred to as CsI). Alternatively, it is common to use a deposition layer of a granular phosphor in which a very small amount of a trivalent rare earth such as terbium or europium is doped as a luminescence center on a base material of metal oxysulfide, for example, a granular phosphor (hereinafter referred to as GOS) in which Tb is doped on Gd₂O₂S.

As for the area sensor, it is common to form, on a surface of the area sensor at its scintillator side, a protective layer to restrain adverse effects on the photoelectric conversion elements due to adhesion of foreign matters to the surface. In this case, parasitic capacitance markedly occurs in signal lines or the like as described later. A material of the protective layer to be used is a material durable to high temperatures caused at the time of the formation of the scintillator. For example, as an organic material having a high heat resistance, a polyimide resin and an epoxy resin can be used in particular.

For example, the polyimide resin as the organic material has a high chemical resistance and therefore is soluble only in a solvent having a polar group. Examples of the solvent having a polar group include N-methyl-2-pyrrolidone (hereinafter referred to as NMP), N,N-dimethyl formaldehyde, N,N-dimethylacetamide, cyclohexanone, cyclopentanone, and the like. Further, in a case of the epoxy resin, an organic substance having a hydroxy group as a prepolymer, such as bisphenol A, is used. Further, an organic substance or acid anhydride having an amino group is used as a curing agent, so that hydroxy groups included in a residual curing agent, a principal chain, and a side chain remain behind in the sensor protective layer. This may cause such a problem that the solvent having a polar group may remain behind in a resin layer after the protective layer has been formed.

If a polar solvent or a polar group remains behind in the protective layer, a difference in parasitic capacitance occurs between a bias line connected to the conversion element via the protective layer and a signal line for transmitting an electric signal from the conversion element, which may cause unevenness in image. In regard to this problem, U.S. 2009/0040348 A1 proposes the followings. In U.S. 2009/0040348 A1, a plurality of bias lines and a plurality of signal lines are provided alternately at predetermined intervals in an area in a protective layer. The plurality of bias lines is commonized outside the area of the protective layer by connection lines provided so as to intersect with the plurality of signal lines.

However, the method in U.S. 2009/0040348 A1 may cause a difference in parasitic capacitance between a plurality of photoelectric conversion elements due to application unevenness in the protective layer, so that unevenness in image due to the difference in parasitic capacitance may occur.

The present invention is accomplished in view of the above problems, and is able to provide a detecting apparatus and a radiation detecting system each of which is able to suppress unevenness in image due to a difference in parasitic capacitance between a plurality of photoelectric conversion elements.

### SUMMARY OF THE INVENTION

A detecting apparatus according to the present invention includes a plurality of photoelectric conversion elements, a protective layer made from an organic material provided so as to cover the plurality of photoelectric conversion elements, and a conductive member provided between the plurality of photoelectric conversion elements and the protective layer so as to cover the plurality of photoelectric conversion elements and receiving a predetermined potential.

A detection system according to the present invention includes the detecting apparatus, signal processing unit for processing a signal from the detecting apparatus, storage unit for storing the signal from the signal processing unit, display unit for displaying the signal from the signal processing unit, transmission processing unit for transmitting the signal from the signal processing unit, and a radiation source for generating radiation.

According to the present invention, parasitic capacitance to occur between a plurality of photoelectric conversion elements and a protective layer is largely restrained, and a difference in parasitic capacitance between the plurality of photoelectric conversion elements is restrained. As a result, a detecting apparatus and a radiation detecting system each of which is able to restrain unevenness in image due to a difference in parasitic capacitance between a plurality of photoelectric conversion elements can be provided.

Further features of the present invention will become apparent from the following description of exemplary embodiments with reference to the attached drawings.

### BRIEF DESCRIPTION OF THE DRAWINGS

FIG. 1 is a schematic plane view of a detecting apparatus according to a first embodiment.

FIG. 2A is a schematic sectional view of the detecting apparatus according to the first embodiment taken along a line IIA-IIA in FIG. 1.

FIG. 2B is a schematic sectional view of the detecting apparatus according to the first embodiment taken along a line IIB-IIB in FIG. 1.

FIG. 2C is a schematic sectional view of the detecting apparatus according to the first embodiment taken along a line IIC-IIC in FIG. 1.

FIG. 3 is a schematic view illustrating a structure of the detecting apparatus according to the first embodiment.

FIG. 4 is a plane schematic view of a radiation detecting apparatus according to another example of the first embodiment.

FIG. 5 is a plane view illustrating a structure of the detecting apparatus according to the another example of the first embodiment.

FIG. 6A is a plane schematic view of a detecting-apparatus according to a second embodiment.

FIG. 6B is a schematic sectional view of the detecting apparatus according to the second embodiment.

FIG. 7 is a schematic view illustrating an application example of the detecting apparatus according to the present invention to a radiation detecting system.

### DESCRIPTION OF THE EMBODIMENTS

Embodiments of the present invention will be described below with reference to drawings. Note that, in the present specification, radiation includes electromagnetic waves such as α-rays, β-rays, and γ-rays, other than X-rays.

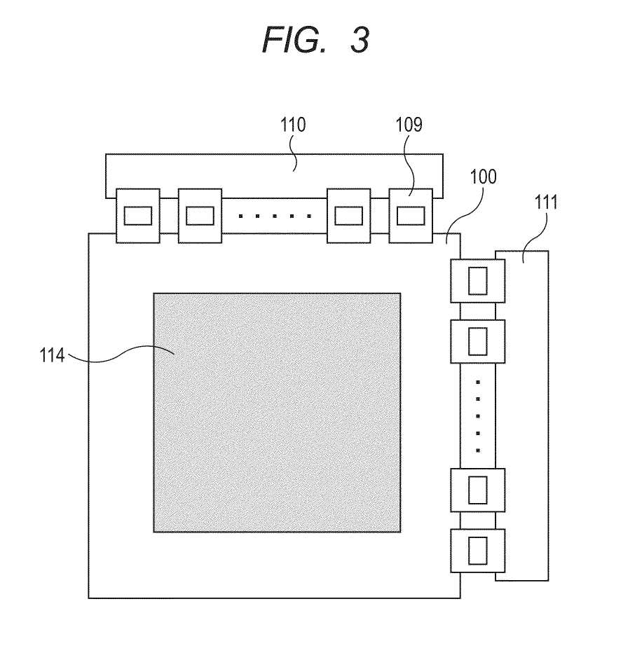

Initially, a detecting apparatus is described with reference to FIG. 3. The detecting apparatus includes: a sensor substrate 100 including a pixel area 114 in which a plurality of pixels are provided in a matrix manner, which will be described later; a driving circuit 111 for driving the pixel array 114; and a reading circuit 110 for reading an electric signal from a pixel. The driving circuit 111 and the reading circuit 110 are electrically mounted on the sensor substrate 100 via external lines 109 of a flexible wiring board or the like.

### First Embodiment

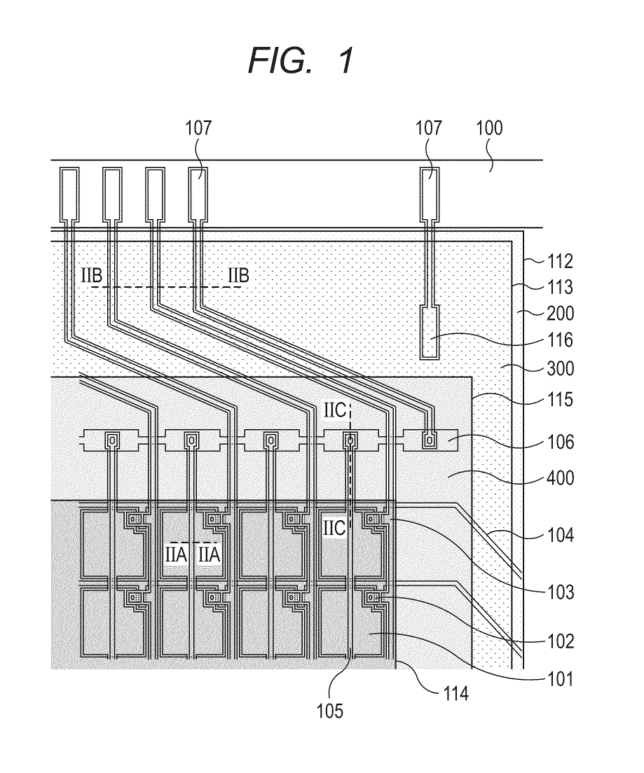

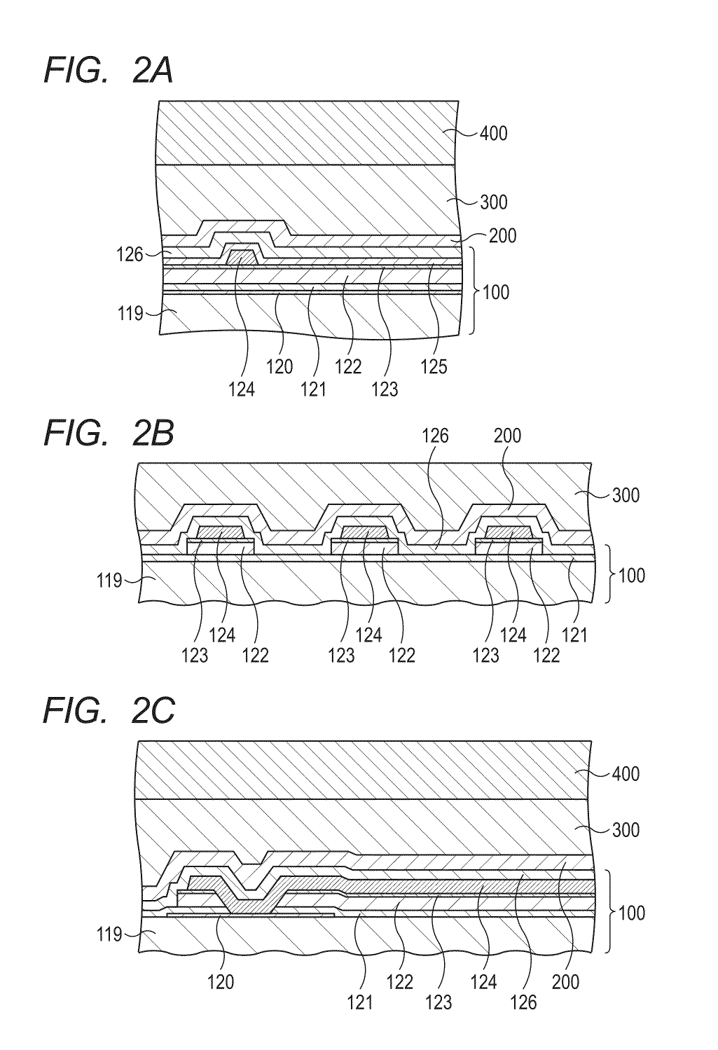

Next will be described a sensor substrate 100 of a detecting apparatus according to a first embodiment of the present invention with reference to FIG. 1 and FIG. 2, FIG. 2A to FIG. 2C correspond to sections respectively taken along broken lines IIA, IIB, and IIC illustrated in FIG. 1. Note that, for the simplification of the description, FIG. 1 illustrates a pixel area 114 of 2 rows×4 columns, but in practice, a sensor substrate is configured such that 2000×2000 pixels, for example, are provided.

The sensor substrate 100 is a sensor panel for converting light converted from radiation by a scintillator 400 provided in an area 115, into an electric signal. As illustrated in FIG. 1, in the sensor substrate 100, a plurality of pixels each including a photoelectric conversion element 101, which is a conversion element, and a TFT 102, which is a switching element, are provided in a matrix manner on an insulating substrate 119 made from glass or the like, thereby forming a pixel area 114.

The photoelectric conversion element 101 converts, into an electric charge, the light converted from radiation by the scintillator 400, and materials such as amorphous silicon and polysilicon can be used therefor, for example. As illustrated in FIG. 2A, a configuration of the photoelectric conversion element 101 is not limited in particular, and an MIS-type sensor, a PIN-type photodiode, a TFT-type sensor, a CMOS-type sensor, or the like can be used appropriately.

Note that the present embodiment deals with a MIS-type photoelectric conversion element. The photoelectric conversion element 101 includes a first conductive layer 120 serving as a first electrode, an insulating layer 121, a semiconductor layer 122, an impurity semiconductor layer 123, a second conductive layer 124, and a third conductive layer 125 serving as a second electrode, which are sequentially provided in layers on the insulating substrate 119, and is covered with an insulating layer 126. Here, the second conductive layer 124 is a bias line 105, which will be described later.

A plurality of signal lines 103 is provided in one direction (a row direction), respectively connected to either ones of sources and drains of the TFTs 102 of the plurality of pixels provided in another direction (a column direction) different from the one direction, and then connected to the reading circuit 110. The signal line 103 is a wiring line for transmitting a signal based on an electric charge caused by photoelectric conversion by the photoelectric conversion element 101, to a reading circuit 110 via the TFT 102.

A plurality of driving lines 104 are provided in the another direction, respectively connected to gates of the TFTs 102 of the plurality of pixels provided in the one direction, and then connected to a driving circuit 111. When a TFT 102 is selected per row by the driving circuit 111 via the driving line 104, a signal photoelectrically converted by the photoelectric conversion element 101 is read out by the TFT 102 and is output to the reading circuit 110 via an external line 109 connected to a connecting terminal 107. Further, the other one of the source and the drain of the TFT 102 is connected to the first electrode, which is one electrode of the Photoelectric conversion element 101.

A plurality of bias lines 105 is arranged in the one direction and respectively connected to second electrodes, which are the other electrodes of the Photoelectric conversion elements 101 of the plurality of pixels provided in the another direction. The bias line 105 is a wiring line for applying a voltage (Vs) to the second electrode of the photoelectric conversion element 101 so as to cause the photoelectric conversion element 101 to perform photoelectric conversion. The bias line 105 is connected to a power supply unit (not illustrated) provided within the reading circuit 110 via a connection line 106, an external connection electrode 107, and an external line 109, which will be described later. The plurality of bias lines 105 is connected to the connection line 106 provided outside the pixel area 114 and the connection line 106 intersects with the plurality of signal lines 103.

As illustrated in FIG. 2C, the connection line 106 is constituted by the first conductive layer 120 and is connected to the bias line 105 constituted by the second conductive layer 124 via a contact hole provided in the insulating layer 121, the semiconductor layer 122, and the impurity semiconductor layer 123. Further, the connection line 106 intersects with the signal line 103 constituted by the second conductive layer 124 with the insulating layer 121, the semiconductor layer 122, and the impurity semiconductor layer 123 sandwiched therebetween.

A wiring line for connecting the connecting terminal 107 and the connection line 106, and the connecting terminal 107 are constituted by the second conductive layer 124, as illustrated in FIG. 2B. The connecting terminal 107 is connected to the external line 109 via a solder, an anisotropic conductive adhesive film (ACF) or the like. A surface of the sensor substrate 100 excluding a part above the connecting terminal 107 is covered with a passivation layer 126, and examples of a material of the passivation layer 126 include an inorganic insulation material such as SiN, TiO₂, LiF, Al₂O₃, MgO, and SiO₂.

The scintillator 400 converts radiation such as an X-ray into light within a wavelength bandwidth detectable by the photoelectric conversion element 101. Examples of a material of the scintillator 400 include any scintillator materials of alkali halides and metal oxysulfides.

As the alkali halides, a material in which Tl or Na is doped on cesium iodide (hereinafter referred to as CsI:Tl, CsI:Na), a material in which Tl is doped on cesium bromide (CsBr:Tl) , and the like are used. In a case where an alkali halide material is used, the scintillator 400 can be formed by vacuum deposition of the alkali halide material on a sensor protective layer 300 formed on the sensor panel 100. During the vacuum deposition, the sensor substrate 100 is heated to 100° C. to 200° C. due to radiant heat and heating by a heater. On that account, as the sensor protective layer 300, which will be described later, it is necessary to use a material which does not change in quality at a temperature during the vacuum deposition.

As the metal oxysulfides, a granular scintillator material (e.g., Gd₂O₂S:Tb which is referred to as GOS) in which a very small amount of a trivalent rare earth such as terbium or europium is doped as a luminescence center on a base material of metal oxysulfide, or the like is used. In a case where a metal oxysulfide material is used, a paste obtained by dispersing the scintillator material in an organic solvent called a vehicle is prepared. The scintillator 400 can be obtained in such a manner that after the vehicle is applied on the sensor protective layer 300 by a method such as screen printing or slit coating, the organic solvent is removed by heating.

The vehicle contains an organic resin called a binder for binding metal oxysulfides and a solvent for dissolving the binder. When a blending amount of the binder is set to about 10% or less of the weight of the vehicle, it is possible to increase a filling factor of the scintillator material, thereby attaining the scintillator 400 with high luminance. As the solvent contained in the vehicle, a solvent having a low molecular weight and including a hydroxy group, such as water and an alcohol solvent, can be used in view of environmental problems these days. Accordingly, the binder is any organic resin soluble to water or an alcohol solvent, for example, resins of polyvinylacetal, polyvinyl alcohol, polyvinylpyrrolidone, polyvinylbutyral, celluloses, and acrylics, each of which has a polar group. Further, as the binder, a polyvinylacetal resin of S-LEC KW (manufactured by Sekisui Chemical Co., Ltd.) which is soluble to water or S-LEC B series (manufactured by Sekisui Chemical Co., Ltd.) which is soluble to ethanol, and the like can be used. The scintillator 400 made by using such a scintillator material of metal oxysulfides can be adhered to the protective layer 300, which is described below, by the binder.

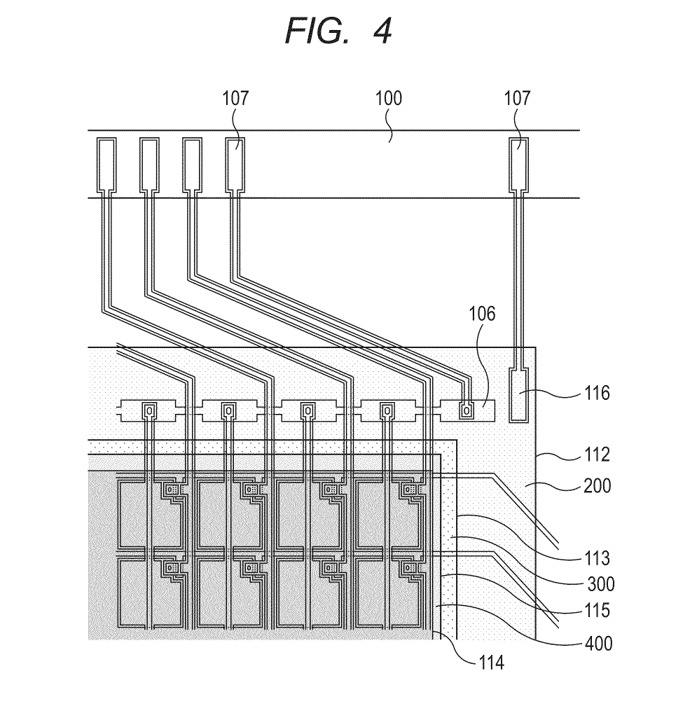

The protective layer 300 for restraining adverse effects on the photoelectric conversion element 101 due to adhesion of foreign substances to a surface is provided in an area 113 of the sensor substrate 100 so as to cover at least the pixel area 114. Note that in the configuration illustrated in FIG. 1, the protective layer 300 is provided in the area 113 placed in vicinity to the connecting terminal 107 so as to cover the pixel area 114, the bias lines 105, and the connection line 106. However, the present invention is not limited to this, and the area 113 should be placed so as to cover at least the pixel area 114, as illustrated in FIG. 4.

Note that, in the present embodiment, in order to finely pass the light converted by the scintillator 400 to the photoelectric conversion element 100, a material having optical transparency to the light (visible light or the like) converted by the scintillator 400 can be used as a material of the protective layer 300. The material of the protective layer 300 is an organic material durable to a heat treatment at the time of the formation of the scintillator, and a polyimide resin and an epoxy resin can be used in particular.

Such an organic material may cause a polar group to remain behind in at least one of a principal chain, a side chain, and a solvent in constituent materials of the sensor protective layer 300. Such a polar group

corresponds to an atom group represented by a hydroxy group (—OH) , a carbonyl group (—C═O), a carboxyl group (—COOH), a cyano group (—CN) , an amino group (—NRR′), a nitro group (—NO₂), and the like. Further, at least one of a positive ion and a negative ion may be included, as a catalyst or impurities, in the solvent used to form the protective layer 300 made from an organic material. Metal ions such as Na⁺ and Ca2⁺ are often seen as the positive ion, while the negative ion encompasses Cl⁻, OH⁻, CN⁻, I⁻, and the like.

A content of the solvent having such a polar group in the sensor protective layer 300 can be set to about 5% or less, from the viewpoint that the sensor protective layer 300 is formed by drying, for example, at about 200° C. to 230° C. A conceivable method for forming the sensor protective layer 300 may be a formation method by a slit coater, a spin coater, a screen printer, vapor deposition, or CVD. In a case where the sensor protective layer is formed by application, the application is easily performed if a viscosity is 2000 mPas or less. In the meantime, in a case where the sensor protective layer is formed by a vacuum process, a lower evaporating temperature can restrain a temperature rise of the sensor substrate 100. As the polyimide resin, LP-62 manufactured by Toray Industries, Inc. can be used from the viewpoint of viscosity and transparency. As the epoxy resin, RO-7198 manufactured by Sanyu Rec Co., Ltd. or CV5133I manufactured by Panasonic Electric Works Co., Ltd can be used from the viewpoint of viscosity and transparency.

As such, when the protective layer 300 in which a polar group or a polar solvent may remain behind is provided so as to cover the plurality of photoelectric conversion elements 101 in the pixel area 114, parasitic capacitance may occur due to the polar group or the polar solvent. Further, the parasitic capacitance may vary between the plurality of photoelectric conversion elements 101 due to unevenness in thickness of the protective layer 300. This may cause unevenness in image due to a difference in the parasitic capacitance. In view of this, a conductive member 200 to cover the plurality of photoelectric conversion elements 101 is provided between the plurality of photoelectric conversion elements 101 and the protective layer 300. A predetermined constant potential is supplied to the conductive member 200, so that a potential of the conductive member 200 is fixed to the predetermined constant potential.

In the present embodiment, as illustrated in FIGS. 1A to 2C, the conductive member 200 is formed on the second insulating layer 126. In a case where the conductive member 200 to which a constant potential is supplied is provided between the plurality of photoelectric conversion elements 101 and the protective layer 300 as such, even if a material having a polar group or ions remains behind in the protective layer 300, the parasitic capacitance due to the polar group or the like can be reduced. Therefore, the occurrence of unevenness in image caused due to a difference in parasitic capacitance between the plurality of photoelectric conversion elements 101 can be restrained. This predetermined potential can be a constant potential.

The conductive member 200 can have optical transparency to the light (visible light) converted by the scintillator 400. Particularly, the conductive member 200 can have an optical transmittance of 70% or more in a wavelength range from 500 to 600 nm. In other words, to have optical transparency indicates that a transmittance to target light is 70% or more. Further, a specific resistance of the conductive member 200 can be set to 1×10⁻³ Ω·cm or less. More specifically, a transparent conductive oxide formed with a thickness of 1 μm or less, such as ITO (indium tin oxide), ZnO (zinc oxide), or indium oxide, can be used as the conductive member.

Further, as illustrated in FIG. 1, the conductive member 200 is provided in an area indicated by a reference numeral 112, and this area 112 can be provided to be broader than the area 113 where the protective layer 300 is provided. In other words, a peripheral portion of the area 112 where the conductive member 200 is provided can be placed between a peripheral portion of the area 113 where the protective layer 300 is provided and a peripheral portion of the sensor substrate 100.

In the configuration illustrated in FIG. 1, the conductive member 200 is provided so as to extend in vicinity to the connecting terminal 107. However, the present invention is not limited to this, and for example, as illustrated in FIG. 4, the peripheral portion of the area 112 may be provided at a position in proximity to the connection line 106 between the connection line 106 and the peripheral portion of the sensor substrate 100. In such a case, the peripheral portion of the area 113 where the protective layer 300 is provided can be provided so as to be placed between the pixel area 114 and the connection line 106.

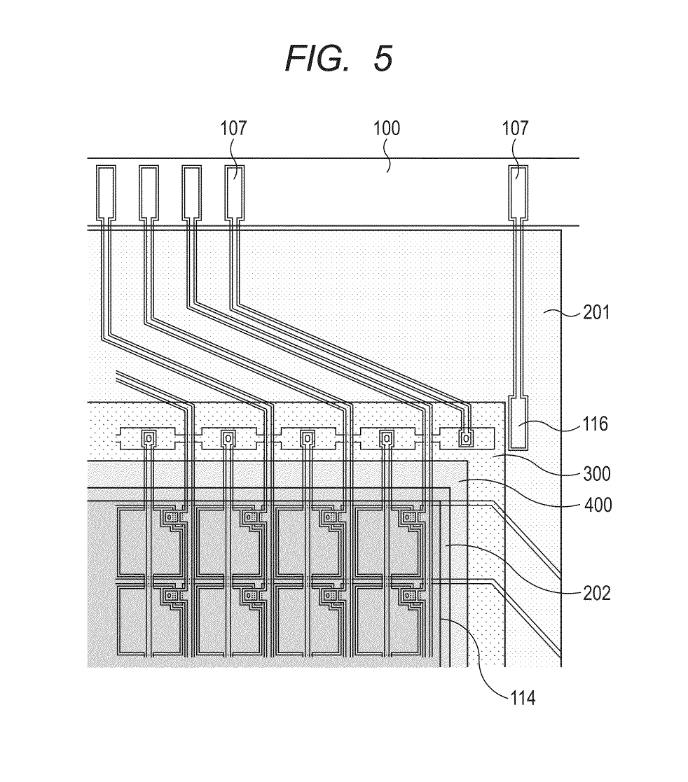

Further, in a case where the conductive member 200 is provided, for example, on other areas as well as the pixel area 114, it is not necessary for the other areas to pass the light converted by the scintillator 400 therethrough. In view of this, it is not necessary to use a conductive material having transparency for that part of the conductive member 200 which is placed on the other areas except the pixel area 114. For such a part, metals such as Al, Cu, Au, and Ag having a high conductivity and having an optical transparency lower than that of ITO and the like can also be used, thereby resulting in that the use of expensive rare metal such as indium can be restrained in consideration of environmental conservation and manufacturing cost. More specifically, as illustrated in FIG. 5, the conductive member 200 includes a first conductive member 201 provided between a peripheral portion of the pixel area 114 and an end of the sensor substrate 100, and a second conductive member 202 provided so as to cover the pixel area 114 and connected to the first conductive member. The first conductive member 201 is constituted by a material having a transmittance lower than that of a material of the second conductive member 202 with respect to the light converted by the scintillator 400.

In either case, the scintillator 400 can be provided in an area 115 having a peripheral portion placed between the peripheral portion of the pixel area 114 and the peripheral portion of the area 113. A method for supplying a predetermined potential to the conductive member 200 is as follows: As illustrated in FIG. 1, an electrode 116 connected to the conductive member 200 and the connecting terminal 107 is provided. The conductive member 200 is connected to a power supply unit provided in the reading circuit 110 via the electrode 116, the connecting terminal 107, and the external line 109, so that the power supply unit supplies a predetermined potential to the conductive member 200.

Here, when the conductive member 200 has the same potential as the bias lines 105 (or the signal lines 103), a potential difference with respect to each line can be eliminated, thereby restraining parasitic capacitance. In this case, the power supply unit supplies a potential to the conductive member 200 so that the potential is equivalent to that of the bias lines 105 (or the signal lines 103). Particularly, since the bias lines 105 are close to the conductive member 200, when the conductive member 200 has the same potential as the bias lines 105, a large parasitic-capacitance reduction effect can be yielded. Note that in a case where the conductive member 200 is controlled to have the same potential as the signal lines 103, the conductive member 200 may be electrically divided into pieces corresponding to respective signal lines 103 in a stripe-like manner, so that a potential can be controlled independently per divided conductive member.

With this configuration, respective stripe-like conductive members corresponding to the respective signal lines 103 can individually be controlled so as to have the same potentials as the respective signal lines 103, thereby parasitic capacitance can be more surely restrained. In this case, it is conceivable that an I TO thin film or the like, for example, corresponding to the conductive member 200 is deposited, and then the ITO thin film is divided into respective conductive members by lithography and dry-etching.

### Second Embodiment

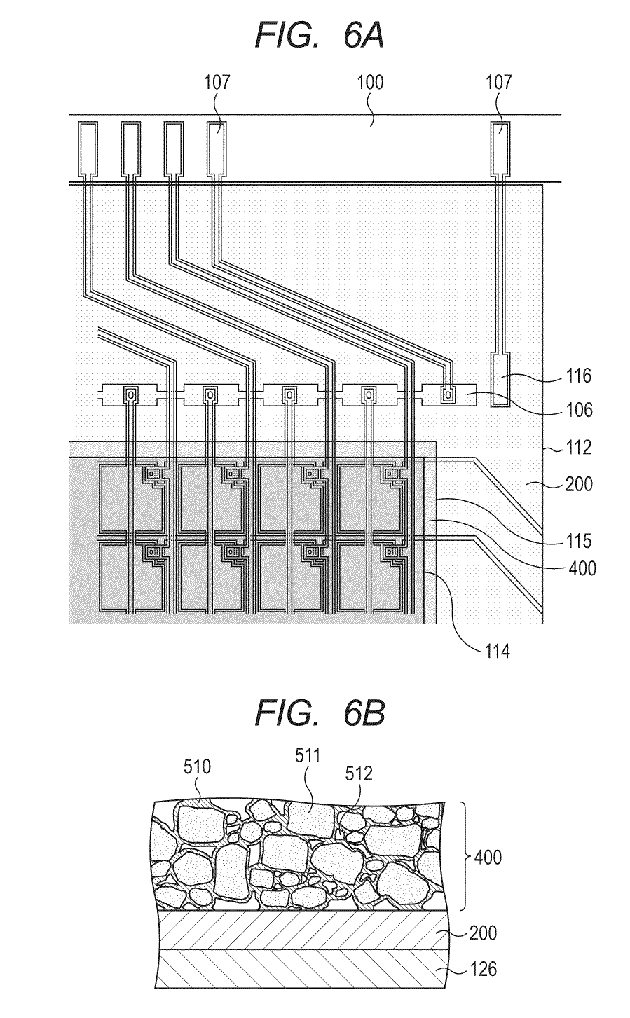

Next will be described a structure of a radiation detecting apparatus, which is a detecting apparatus according to a second embodiment, with reference to FIGS. 6A and 6B. As illustrated in FIG. 6B, the present embodiment uses a scintillator 400 including a plurality of granular scintillator materials 511 bound to each other by a binder 510 as a metal-oxysulfide scintillator material, and partially including air gaps 512. The binder 510 in a paste of the scintillator 400 has a protection function. That is, instead of the protective layer 300 in the first embodiment, the binder 510 included in the scintillator 400 is used as a protective layer.

The binder is an organic resin. In recent years, organic resins soluble to water or alcohol such as ethanol have been often used from the viewpoint of environmental protection, but these resins often include a polar group. On that account, direct application of such resins onto a sensor sometimes causes unevenness in image.

In the present embodiment, the binder 510 adheres to the conductive member 200, and the conductive member 200 exists between a plurality of photoelectric conversion elements 101 and the scintillator 400. The plurality of Photoelectric conversion elements 101 is hereby electrically shielded by the conductive member 200, thereby the scintillator 400 including the binder 510 having polarity can be provided at a given position on the conductive member 200. As such, even if an organic material having a polar group, such as the binder 510, is provided on each wiring line or the pixel area 114, variation in parasitic capacitance is restrained by effects of the conductive member 200, so that unevenness in image can be restrained.

### Third Embodiment

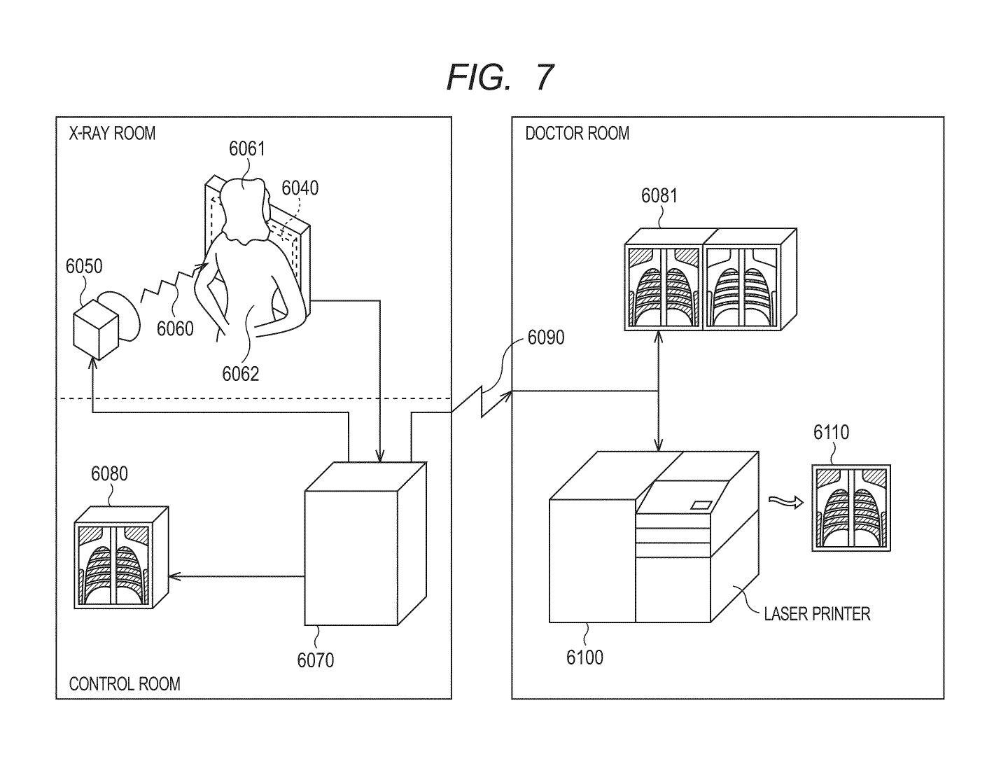

The present embodiment discloses a radiation detecting system in which the detecting apparatus selected from the first and second embodiments is applied to an X-ray diagnosis system. FIG. 7 is a schematic view illustrating a radiation detecting system according to the present embodiment.

In this radiation detecting system, an X-ray 6060 generated by an X-ray tube 6050, which is a radiation source, passes through a chest 6062 of a patient (or an examinee) 6061 and is incident on a radiation detecting apparatus (an image sensor) 6040. This radiation detecting apparatus 6040 is selected from the first and second embodiments. The X-ray thus incident thereon includes information about an inside of a body of the patient 6061. A scintillator emits light in response to the incidence of the X-ray, and photoelectric conversion elements of a sensor substrate photoelectrically convert this light, so that an electric signal is obtained. This information is converted into a digital signal and subjected to an image process by an image processor 6070 serving as signal processing unit, so that the information can be observed by a display 6080 serving as displaying unit in a control room.

Further, this information can be transmitted to a distant place by transmission processing unit (a telephone line 6090 in the example in the figure) such as networks including a telephone line, LAN, the Internet, and the like. The information thus transmitted is able to be displayed on a display 6081 serving as display unit in a doctor room or the like located at a different place, or to be stored in storage unit such as an optical disk. This allows a doctor at a distant place to make a diagnosis. Further, the information can be stored in a film 6110 by a film processor 6100 serving as storage unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-138074 filed on Jun. 19, 2012, which is hereby incorporated by reference herein in its entirety.

What is claimed is:

1. A detecting apparatus comprising:
a plurality of photoelectric conversion elements;
a protective layer made from an organic material provided so as to cover the plurality of photoelectric conversion elements; and
a conductive member provided between the plurality of photoelectric conversion elements and the protective layer so as to cover the plurality of photoelectric conversion elements and receiving a predetermined potential.

2. The detecting apparatus according to claim 1, further comprising:
a power supply unit arranged to supply the predetermined potential to the conductive member.

3. The detecting apparatus according to claim 2, further comprising:
a plurality of TFTs each provided so as to correspond to each of the plurality of photoelectric conversion elements;
a signal line arranged to transmit a signal based on an electric charge generated by photoelectric conversion by the photoelectric conversion element; and
a reading circuit ted to the signal line to read the signal,
wherein the photoelectric conversion element includes a first electrode provided on a substrate, a second electrode provided on the first electrode, and a semiconductor layer provided between the first electrode and the second electrode,
the TFT includes source and drain electrodes, one of the source and drain electrodes is connected to the first electrode, and the other one of the source and drain electrodes is connected to the signal line,
a bias line arranged to apply, to the second electrode, a voltage for causing the photoelectric conversion element to perform photoelectric conversion is connected to the second electrode, and
the power supply unit supplies the predetermined potential to the conductive member so that the conductive member has the same potential as either one of the bias line and the signal line.

4. The detecting apparatus according to claim 1, further comprising:
a scintillator arranged to convert radiation into light in a wavelength bandwidth detectable by the photoelectric conversion elements, wherein:
the conductive member has optical transparency to the light.

5. The detecting apparatus according to claim 4, wherein:
the protective layer has optical transparency.

6. The detecting apparatus according to claim 5, wherein:
the conductive member is constituted by a transparent conductive oxide.

7. The detecting apparatus according to claim 4, wherein:
the scintillator includes a plurality of granular scintillator materials, and a binder arranged to bind the plurality of granular scintillator materials, and
the protective layer is the binder.

8. The detecting apparatus according to claim 1, wherein:
the protective layer contains at least one of a polar group, a positive ion, and a negative ion in at least one of a principal chain, a side chain, and a solvent in constituent materials.

9. The detecting apparatus according to claim 8, wherein:
a content of the solvent having a polar group in the protective layer is 5% or less.

10. A radiation detecting system comprising:
the detecting apparatus according to claim 1;
signal processing unit configured to process a signal from the detecting apparatus;
storage unit configured to store the signal from the signal processing unit;
display unit configured to display the signal from the signal processing unit; and
transmission processing unit configured to transmit the signal from the signal processing unit.

11. The radiation detecting system according to claim 10, further comprising:
a radiation source arranged to generate a radiation.
